(19) United States
(12) Patent Application Publication
(10) Pub. No.: US 2003/0041802 A1
(43) Pub. Date: Mar. 6, 2003

(54) Vacuum pumping system and method for monitoring of the same

(75) Inventors: Masayuki Tanaka, Kanagawa-ken (JP); Takashi Nakao, Kanagawa-ken (JP); Yukihiro Ushiku, Kanagawa-ken (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/224,255

(22) Filed: Aug. 21, 2002

(30) Foreign Application Priority Data
Aug. 31, 2001 (JP) P2001-263533

(51) Int. Cl. C23C 16/00

(52) U.S. Cl. 118/715

(57) ABSTRACT

A vacuum pumping system includes: an evacuation conduit, having a sequence of monitoring zones serially assigned in an exhaust direction; sensors respectively provided to the monitoring zones and independently detecting the conditions of the monitoring zones; heaters respectively provided to the monitoring zones and being paired with the sensors; and a control unit receiving data signals from the sensors, comparing the data signals with a threshold value, and when the data signals from a specific sensor exceed the threshold value, selectively supplying heating power to a heater of the monitoring zone where the specific sensor is provided.

### CROSS REFERENCE TO RELATED APPLICATIONS

This application is based upon and claims the benefit of priority from prior Japanese Patent Application 2001-263533 filed on Aug. 31, 2001; the entire contents of which are incorporated by reference herein.

### BACKGROUND OF THE INVENTION

1. Field of the Invention

The present invention relates to a vacuum pumping system, which is used in general industry or in a semiconductor manufacturing equipment. In particular, it is related to a vacuum pumping system, which provides improved longevity through failure prevention thereof.

2. Description of the Related Art

Problems of the conventional vacuum pumping system often utilized in general industry or in many semiconductor manufacturing equipments will be described. As an example, problems relating to the vacuum pumping system, which is used in a low-pressure chemical vapor deposition (LPCVD) equipment, specifically a tandem pump system, which is used in a LPCVD equipment for a silicon nitride film (Si₃N₄ film), will be described.

Conventionally, deposition of a silicon nitride film through a LPCVD method involves the chemical reaction of dichlorosilane (SiH₂Cl₂) gas, which is used as a silicon source, and ammonia (NH₃) gas, which is used as a nitride species, under low pressure conditions at approximately 800° C. to deposit a silicon nitride film upon a silicon (Si) substrate. In addition to generating the silicon nitride, the chemical reaction produces the reaction by-products of ammonium chloride (NH₄Cl) gas and hydrogen (H₂) gas. The hydrogen in gas phase is evacuated through the vacuum pumping system utilizing the LPCVD equipment. On the other hand, since the temperature within the reactor is approximately 800° C. and it is under low pressure conditions of several 100 Pa or less at the time of formation, the ammonium chloride is also in the gas phase. The LPCVD equipment typically has a trap for collecting solid phase by-products, disposed between a LPCVD chamber and the vacuum pumping system.

However, it is impossible to completely collect the solid phase by-products with the trap since pressure at the location of the trap is low. Accordingly, the ammonium chloride that has not been collected reaches the vacuum pumping system. The vacuum pumping system generates an approximately five digits difference in pressure before and after the evacuation pump, where there is approximately 0.1 Pa of pressure on the upstream side and atmospheric pressure on the downstream side under such operational performance. While the ammonium chloride is in a gas phase at the time of formation, it begins to solidify within the evacuation pump as the pressure increases due to gas compression therein. At the portions where solidification has begun, exhaust conductance decreases due to reduction of the pipe radius, and solidification is further accelerated there. In other words, localized solidification that has begun in one portion rapidly accelerates, and the pipes ultimately are blocked, or adhesion to the rotating portions happens making rotation impossible, thereby making the vacuum pumping system fail. Failure of the vacuum pumping system maybe caused by catastrophic failure in just one portion, resulting in an vacuum pumping system with a remarkably short life span.

### SUMMARY OF THE INVENTION

A first aspect of the present invention inheres in a vacuum pumping system including: an evacuation conduit, having a sequence of monitoring zones serially assigned in an exhaust direction; sensors respectively provided to the monitoring zones and independently detecting the conditions of the monitoring zones; heaters respectively provided to the monitoring zones and being paired with the sensors; and a control unit receiving data signals from the sensors, comparing the data signals with a threshold value, and when the data signals from a specific sensor exceed the threshold value, selectively supplying heating power to a heater of the monitoring zone where the specific sensor is provided.

A second aspect of the present invention inheres in a vacuum pumping system, being connected such that a group of evacuation elements regulate a fixed evacuation direction, including: a specific evacuation element included among the group of the evacuation elements; a first valve connected to a suction side piping of the specific evacuation element; a branching vacuum piping, having an exhaust side piping connected to the first valve; a second valve connected to other exhaust side piping of the branching vacuum piping; a bypass piping having a suction side piping connected to the second valve; other evacuation elements connecting one of the suction side piping to an exhaust side piping of the specific evacuation element, and the other suction side piping to an exhaust side piping of the bypass piping; sensors connected to at least one of the suction side piping of the specific evacuation element, the exhaust side piping of the specific evacuation element, and a main body of the specific evacuation element; and a control unit receiving data signals from the sensors, comparing the data signals with a threshold value, and when the data signals exceed the threshold value, respectively supplying signals for closing the first valve and opening the second valve to the first and second valves.

A third aspect of the present invention inheres in a method for monitoring an evacuation conduit including: evacuating a reactive gas and a reaction by-product of the reactive gas by the evacuation conduit having a plurality of monitoring zones serially arranged in an evacuation direction; independently detecting respective conditions of the monitoring zones by sensors provided respectively to the monitoring zones; receiving respective data signals from the sensors; comparing the data signals with a threshold value; and selectively supplying heating power to only a heater of the monitoring zone where the specified sensor is arranged, when the data signals from a specific sensor exceeds the threshold value.

A fourth aspect of the present invention inheres in a method for monitoring an evacuation conduit including: evacuating a reactive gas and a reaction by-product of the reactive gas, by the evacuation conduit, including a first valve connected to a suction side piping of a specific evacuation element, a branching vacuum piping having an exhaust side piping connected to the first valve, a second valve connected to other exhaust side piping of the branching vacuum piping, a bypass piping having a suction side piping connected to the second valve; detecting a condition of the specific evacuation element by sensors connected to at least one of the suction side piping of the specific evacuation element, the exhaust side piping of the specific evacuation element, and the main body of the specific evacuation element; and receiving data signals from the sensors, comparing the data signals with a threshold value, and when the data signals from a specific sensor exceeds the threshold value, supplying respectively signals for closing the first valve and opening the second valve to the first and second valves.

### BRIEF DESCRIPTION OF DRAWINGS

FIG. 1 is a block diagram showing the concept of a vacuum pumping system according to a first embodiment of the present invention;

FIG. 2 is a block diagram schematically showing in more detail the vacuum pumping system according to the first embodiment of the present invention;

FIG. 3 is a block diagram schematically showing a vacuum pumping system according to a second embodiment of the present invention; and

FIG. 4 is a block diagram schematically showing a vacuum pumping system according to other embodiments of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

(FIRST EMBODIMENT)

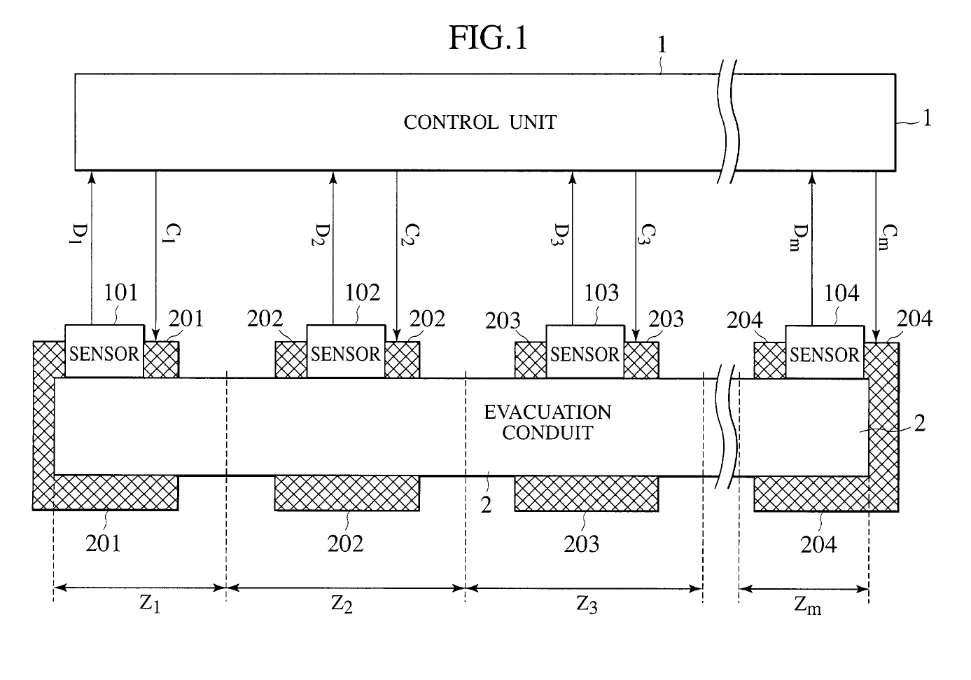

As shown in FIG. 1, a vacuum pumping system according to the first embodiment of the present invention encompasses an evacuation conduit 2, which has a plurality of monitoring zones Z₁, Z₂, Z₃, . . . , Zₘ serially arranged in the exhaust direction; sensors 101, 102, 103, . . . , 104, which are respectively provided to the monitoring zones Z₁, Z₂, Z₃, . . . , Zₘ and each independently detect the condition of the corresponding zones of the evacuation conduit 2 therein; heaters 201, 202, 203, . . . , 204, which are paired with the sensors 101, 102, 103, . . . , 104 and respectively provided to the monitoring zones Z₁, Z₂, Z₃, . . . , Zₘ; and a control unit 1, which respectively receives data signals D₁, D₂, D₃, . . . , Dₘ from the sensors 101, 102, 103, . . . , 104, compares these data signals D₁, D₂, D₃, . . . , Dₘ with a threshold value, and when a data signal D_{J} (J:1-m) from a particular sensor exceeds the threshold value, selectively supplies heating power to only the heater of the monitoring zone the specific sensor is arranged therein. The heating power can be directly supplied to the heaters 201, 202, 203, . . . , 204 from the control unit 1. On the contrary, the necessary heating power can be indirectly supplied by power units, each connected to the heaters 201, 202, 203, . . . , 204, as shown in FIG. 1. That is, the necessary heater control signals C₁, C₂, C₃, . . . , Cₘ from the control unit 1 are respectively supplied to the power units so as to supply heating power to the heaters 201, 202, 203, . . . , 204.

More specifically, in the vacuum pumping system according to the first embodiment of the present invention, the evacuation conduit 2 has a large variety of and a plurality of sensors 101, 102, 103, . . . , 104, which constantly monitor its condition, mounted thereon. The group of a large variety and a plurality of sensors 101, 102, 103, . . . , 104 constantly sends to the control unit 1 the condition of the evacuation conduit 2. Temperature gauges, pressure gauges, flowmeters, ammeters/voltmeters or vibration gauges may be considered as the sensors 101, 102, 103, . . . . 104. A comparator, which compares the received data signals D₁, D₂, D₃, . . . , Dₘ with the threshold value, is provided within the control unit 1. Analog comparison with the threshold value may be made, or alternatively, comparison may be made with a digital circuit.

In the case of comparing with a digital circuit, information from the group of the sensors 101, 102, 103, . . . , 104 passes through an A/D converter, which is provided to the output circuit of the sensors 101, 102, 103, . . . , 104, and is concentrated in the control unit 1 as digital signals. Otherwise, it may be structured such that they are transmitted to the control unit 1 as analog signals, passed through an installed A/D converter of an input circuit of the control unit 1, so as to be input into the comparator after being transformed into digital signals. Employing either method, the information D₁, D₂, D₃, . . . , Dₘ from the group of the sensors 101, 102, 103, . . . , 104 is collected by the control unit 1. For performing further detailed diagnosis/analysis of the information D₁, D₂, D₃, . . . , Dₘ, a central processing unit (CPU) may be installed. The CPU is controlled in conformity with predetermined software.

In this manner, the control unit 1 diagnoses/analyzes the information D₁, D₂, D₃, . . . , Dₘ from the group of sensors 101, 102, 103, . . . . 104, and controls the group of the heaters 201, 202, 203, . . . , 204 based on the results.

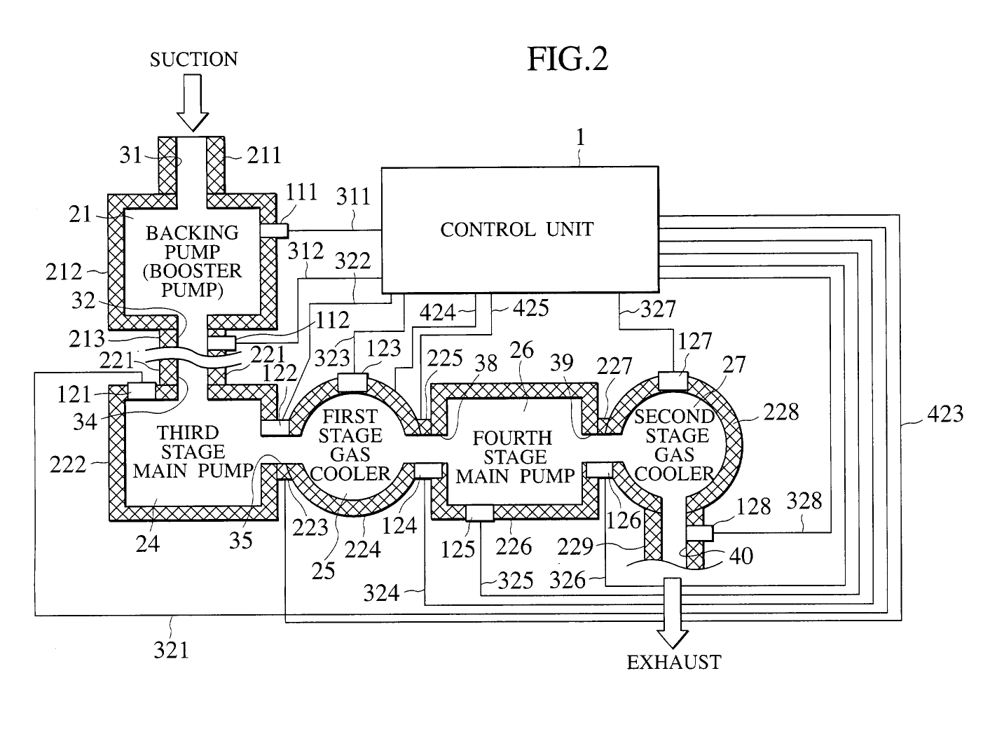

In FIG. 2, a portion of the evacuation conduit 2 of the LPCVD equipment for Si₃N₄ films is illustrated. The evacuation conduit 2 has a plurality of evacuation elements 21, . . . , 24, 25, 26, 27 serially connected in the exhaust direction from the upstream side. The evacuation elements are a backing pump (mechanical booster pump) a first stage main pump (omitted from the drawing), a second stage main pump (omitted from the drawing), a third stage main pump 24, a first stage gas cooler 25, a fourth stage main pump 26, a second stage gas cooler 27, a fifth stage main pump (omitted from the drawing), and a third stage gas cooler (omitted from the drawing) respectively. The evacuation elements 21, . . . , 24, 25, 26, 27 are connected to each other through vacuum piping 32, . . . , 34, 35, 37, 38, 39. In FIG. 2, similarly to FIG. 1, a plurality of monitoring zones are assigned to the evacuation elements 21, . . . , 24, 25, 26, 27. In addition, sensors 111, 112, . . . , 121, 122, 123, 124, 125, 126, 127, 128, which independently detect the condition of the evacuation conduit 2 in the monitoring zones, respectively, and heaters 211, 212, 213, . . . , 221, 222, 223, 224, 225, 226, 227, 228, 229, which are paired with these sensors 111, 112, . . . , 121, 122, 123, 124, . . . , 127, 128 and are respectively provided to the monitoring zones, are arranged corresponding to these monitoring zones. In the following, the sensors 111, 112, . . . , 121, 122, 123, 124, 125, 126, 127, 128 are described as being temperature gauges such as thermocouples or semiconductor thermometers. However, it should be noted that as long as change in the condition of the evacuation conduit 2 can be detected, the sensors 111, 112, . . . , 121, 122, 123, 124, 125, 126, 127, 128 are not limited to being temperature gauges. The control unit 1 receives the respective data signals from the sensors 111, 112, . . . , 121, 122, 123, 124, 125, 126, 127, 128, compares these data signals to the threshold value, and in the case where a data signal from a specific sensor exceeds the threshold value, operates so as to selectively supply heating power to only the heater in the monitoring zone where the specific sensor is arranged. Thus, the sensors 111, 112, . . . , 121, 122, 123, 124, 125, 126, 127, 128 and the control unit 1 are connected to each other by wiring 311, 312, . . . , 321, 322, 323, 324, 325, 326, 327, 328. Furthermore, the heaters 211, 212, . . . , 221, 222, 223, 224, 225, 226, 227, 228, 229 and the control unit 1 are connected to each other by wiring, however, in FIG. 2, of these, only the wiring 423, 424, 425 connected to the heaters 223, 224, 225 are shown in the drawing.

During the LPCVD method for the silicon nitride film using dichlorosilane (SiH₂Cl₂) and ammonia (NH₃) as source gases, ammonium chloride (NH₄Cl) gas, a reaction by-product, is generated as a result. Normally, a trap, which collects these unreacted source gases (reactive gases) and the reaction by-product (NH₄Cl) from the reaction of the source gases, is inserted between the evacuation conduit 2 and the CVD reactor (chamber) in the LPCVD equipment. It is impossible for the trap to completely collect the reaction by-product due to low pressure. The reaction by-product that is not collected reaches the evacuation conduit 2. The pressure in the evacuation conduit 2, which has the plurality of evacuation elements 21, . . . , 24, 25, 26, 27, increases from approximately 0.1 Pa to normal atmospheric pressure due to the compression of the gas. The reaction by-product exists as a gas under low pressure conditions; it begins to solidify in accordance with the sublimation curve of the phase diagram as the pressure increases. Within the pump, since the pressure changes from several hundred Pa to the normal atmospheric pressure through repeated compression of the gas, the gaseous reaction by-product within the exhaust gas begins to solidify in the evacuation conduit 2 as the pressure increases. If the solidification begins in the piping of the evacuation conduit 2, the volume of the piping or the gas coolers 25, 27 decreases, and the exhaust conductance decreases. The pressure further increases in the portions of the reaction by-product solidifying/adsorbing, whereby as a result, the temperature begins to rise.

In the control unit 1, the threshold values (permissible values) are set so as to permit the temperature to rise up to approximately a certain degree Celsius in each of the plurality of monitoring zones of the evacuation conduit 2. The threshold values are determined based upon control information, which takes into account the starting condition of the LPCVD equipment and the operating status of the evacuation conduit 2 accumulated up to the present. In the first embodiment, the temperature rise threshold value is set to “a rise of 10° C. from the initial condition”. When the rise in temperature reaches the threshold value, the control unit 1 supplies power to only the heater on the corresponding monitoring zone in the heaters 211, 212, . . . , 221, 222, 223, 224, 225, 226, 227, 228, 229, which are attached inside the plurality of monitoring zones of the evacuation conduit 2, selectively raising the temperature of only the corresponding monitoring zone.

For example, it is assumed that clogging at the piping 35 on the suction side of the first stage gas cooler 25 disposed in upstream begins due to adhesion of the reaction by-product, and a rise in temperature occurs. As previously mentioned, there are three stages of gas coolers in all. In this case, the heater 223 for the piping 35 on the suction side of the first stage gas cooler 25, the heater 225 for the piping 38 on the exhaust side and the heater 224 for the outer wall portion of the first stage gas cooler 25 are heated to 180° C. The preset temperature of the heaters 223, 225, 224 is the temperature at which ammonium chloride sublimes. Accordingly, since a reaction by-product generated by a LPCVD equipment of other material has different properties, the LPCVD equipment for the other material requires setting a temperature corresponding to the reaction by-product. By raising the temperature of the heaters 223, 225 and 224, adhesion of the reaction by-product at the first stage gas cooler 25 stops progressing any further.

By continuing to perform a semiconductor manufacturing process, adhesion and clogging in other monitoring zones progresses and thus changes arise in the condition of the evacuation conduit 2. Similar to the aforementioned processing, the control unit 1 raises the temperature of the corresponding heater in the heaters 211, 212, . . . , 221, 222, 223, 224, 225, 226, 227, 228, 229 to 180° C. when the change in the evacuation conduit 2 condition exceeds the threshold value, which is set for a newly clogged monitoring zone. Successively, dispersing the solidified/adsorbed reaction by-product is possible by repeating the same process (operation).

Conventionally, solidification drastically accelerates in the portions where the reaction by-product has begun to adhere, becoming a catastrophic failure that makes the pump fail. However, according to the first embodiment, it is possible to suppress further adhesion in the portion where clogging has begun, dispersing the reaction by-product to other monitoring zones. Thus, the life span of the LPCVD equipment may be lengthened.

(Second Embodiment)

In the first embodiment, a method for suppressing adhesion of a reaction by-product, which is generated in a portion of the monitoring zones of the evacuation pump system, by heating specific monitoring zones Z1, Z2, Z3, . . . , Zm, however, other methods are also possible.

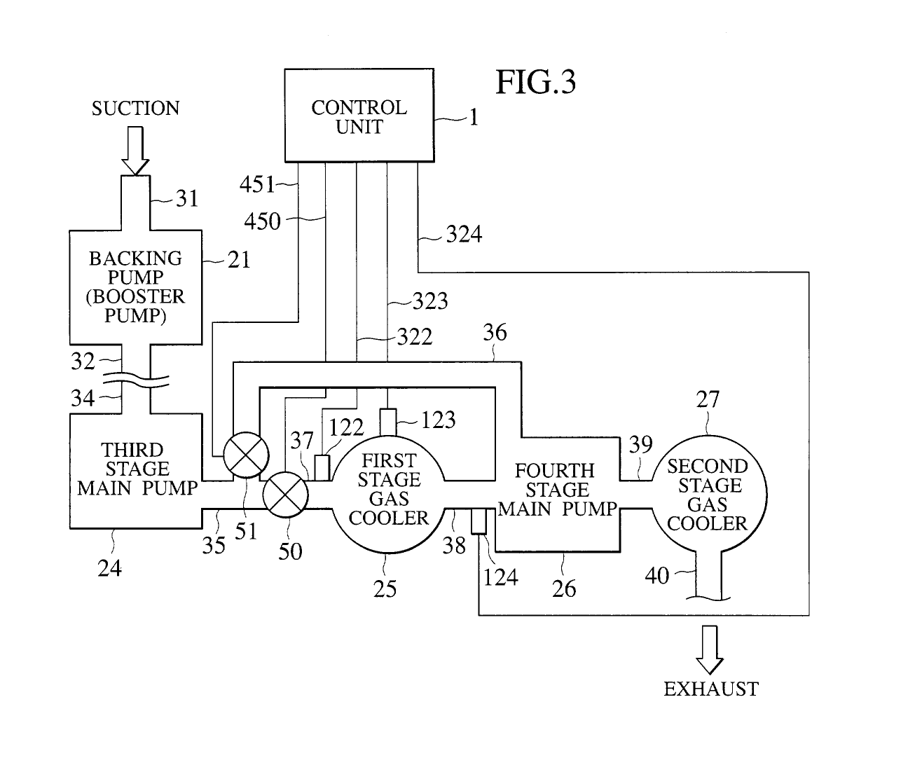

FIG. 3, similar to FIG. 2, shows a portion of an evacuation conduit 2, which has a backing pump (mechanical booster pump) 21, a main pump first stage (omitted from the drawing), a main pump second stage (omitted from the drawing), a main pump third stage 24, a first stage gas cooler 25, a fourth stage main pump 26, a gas cooler second stage 27, a main pump fifth stage (omitted from the drawing), and a gas cooler third stage (omitted from the drawing), serially connected in the evacuation direction from the upstream side. A group of the plurality of evacuation elements 21, . . . , 24, 25, 26, 27 are connected through vacuum piping 32, . . . , 34, 35, 37, 38, 39 so as to define a fixed evacuation direction. The evacuation conduit 2 is described by focusing on the gas cooler first stage as a specific evacuation element 25. A first valve 50 is connected to a suction side piping 37 of the gas cooler first stage (specific evacuation element) 25. One exhaust side piping of a branch vacuum piping 35 is connected to the first valve 50. A second valve 51 is connected to the other exhaust side piping of the branch vacuum piping 35. The suction side piping of a bypass piping 36 is connected to the second valve 51. One suction side piping of the main pump fourth stage as another evacuation element 26 is connected to an exhaust side piping 38 of the first stage gas cooler 25. The other suction side piping of the fourth stage main pump (another evacuation element) 26 is connected to the exhaust side piping of the bypass piping 36.

Here, sensors 122, 123, 124 are provided to the suction side piping 37 of the first stage first stage gas cooler 25, the main frame of the first stage gas cooler 25, and the exhaust side piping 28 of the first stage gas cooler 25. As with the first embodiment, the second embodiment is described with temperature gauges as the sensors. The control unit 1 receives data signals from these sensors 122, 123, 124, compares the data signals with the threshold value, and when these data signals exceed the threshold value, respectively supplies to the first valve 50 and second valve 51 signals for closing the first valve 50 and opening the second valve 51. Consequently, the sensors 122, 123, 124 and the control unit 1 are connected to each other by the wiring 322, 323 and 324. Furthermore, the first valve 50 and second valve 51 are connected to the control unit 1 via respective wiring 450 and 451. In order to open and close the first valve 50 and second valve 51 in conformity with electrical signals from the control unit 1, the first valve 50 and second valve 51 may be magnetic valves or pneumatic valves which operate by air pressure. In the case of the pneumatic valves, the air pressure respectively supplied to the first valve 50 and second valve 51 may be controlled by a pneumatic piping system, which is connected to the first valve 50 and second valve 51. More specifically, the first valve 50 and second valve 51 may be controlled to open and close by driving the magnetic valves, which control the pneumatic piping system, in conformity with electrical signals from the control unit 1.

In this manner, the method depending on the provision of the bypass piping 36 may also allow for lengthening of the evacuation conduit 2 life span. In the initial condition where clogging has not occurred, the first valve 50 is in an open status and the second valve 51 is in a closed status. In other words, gas passes through the first stage gas cooler 25. In the LPCVD equipment for Si₃N₄ films, the upstream side first stage gas cooler 25 often clogs up. If the rise in temperature due to clogging exceeds the threshold value, the control unit 1 closes the first valve 50 and simultaneously opens the second valve 51. The exhaust gas passes through the bypass piping 36 and flows into the fourth stage main pump 26. Namely, if it is conventional, when clogging of the first stage gas cooler 25 occurs, replacement of the entire evacuation conduit 2 is necessary; however, by allowing operation of the portions where clogging has not occurred using the bypass piping 36, lengthening the evacuation conduit 2 life span becomes possible.

It should be noted that the evacuation elements other than the first stage gas cooler 25, such as the backing pump (mechanical booster pump) 21, the first stage main pump (omitted from the drawing), the second stage main pump (omitted from the drawing), the third stage main pump 24, the fourth stage main pump 26, the second stage gas cooler 27, the fifth stage main pump (omitted from the drawing), and the third stage gas cooler (omitted from the drawing), may also be provided automatic valves for switching to the bypass piping.

(Other Embodiments)

The present invention has been described through the first and second embodiments as mentioned above, however the descriptions and drawings that constitute a portion of this disclosure should not be perceived as limiting this invention. Various modified examples of the embodiments, alternative embodiments, working examples and operational techniques will become clear to persons skilled in the art from this disclosure.

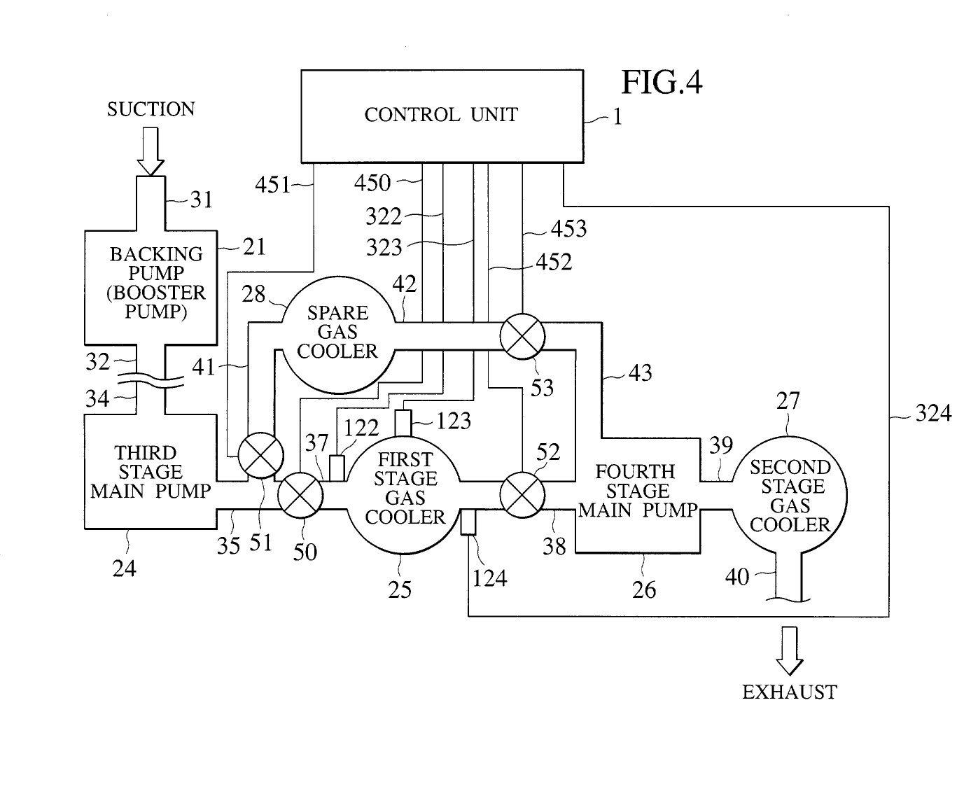

For example, the structure may have other evacuation elements further arranged on the bypass piping 36 side of FIG. 3, which is used in the description of the second embodiment previously described. FIG. 4 is a structure related to a modified example of the second embodiment of the present invention, wherein a spare gas cooler 28 is further arranged on the bypass piping 36 side of FIG. 3. In other words, as shown in FIG. 4, the first valve 50 is connected to the suction side piping 37 of the first stage gas cooler 25, and one of the exhaust side piping of the branch vacuum piping 35 is connected to the first valve 50. The second valve 51 is connected to the other exhaust side piping of the branch vacuum piping 35. A suction side piping of the spare gas cooler 28 is connected to the second valve 51 via a bypass piping 41. A fourth valve 53 is connected to the exhaust side of the spare gas cooler 28 via a bypass piping 42. A third valve 52 is connected to an exhaust side piping 38 of the first stage gas cooler 25, and via the third valve 52, one of the suction side piping of the main pump fourth stage is connected thereto. A bypass piping 43 is connected to the fourth valve 53 exhaust side, and the bypass piping 43 is connected to the other suction side piping of the fourth stage main pump 26.

Similar to FIG. 3, sensors 122, 123, 124 are provided to the suction side piping 37 of the first stage gas cooler 25, the main body of the first stage gas cooler 25, and the exhaust side piping 38 of the first stage gas cooler 25. As the first embodiment, the second embodiment is described with the sensors being temperature gauges. The control unit 1 receives data signals from these sensors 122, 123 and 124, compares the data signals with the threshold value, and when data signals exceed the threshold value, respectively supplies to the first valve 50, second valve 51, third valve 52 and fourth valve 53 signals for closing the first valve 50 and the third valve 52 and opening the second valve 51 and the fourth valve 53. Consequently, the sensors 122, 123, 124 are connected to the control unit 1 via the wiring 322, 323 and 324. Furthermore, the first valve 50, second valve 51, third valve 52 and fourth valve 53 are connected to the control unit 1 via respective the wiring 450, 451, 452 and 453. The fact that in order to open and close the first valve 50, second valve 51 third valve 52 and fourth valve 53 in conformity with electrical signals from the control unit 1, the first valve 50, second valve 51 third valve 52 and fourth valve 53 may be magnetic valves or pneumatic valves, which operate by air pressure, is similar to the case of FIG. 3.

As shown in FIG. 4, since the spare gas cooler 28 is provided between the bypass piping 41 and 42, it is possible to switch over the exhaust channel so that the spare gas cooler 28 is used when clogging of the first stage gas cooler 25 occurs. Then, after switching over to the exhaust channel that uses the spare gas cooler 28, a vacuum flange (omitted from the drawing), which is provided at the portion of the suction side piping 37 and exhaust side piping 38 of the first stage gas cooler 25, is opened, and the first stage gas cooler 25 where clogging occurred there may be overhauled. If both sides or one side of the vacuum flange is connected with a bellows, the disassembling procedure is easy. After overhaul is complete, the first stage gas cooler 25 is once again inserted to the exhaust channel at the vacuum flange (omitted from the drawing) portion of the suction side piping 37 and exhaust side piping 38. By doing as such, next, if clogging on the spare gas cooler 28 side occurs, contrary to the aforementioned, the first valve 50 and third valve 52 are opened, and signals for closing the second valve 51 and fourth valve 53 may be respectively transmitted to the first valve 50, second valve 51, third valve 52 and fourth valve 53 from the control unit 1. For this purpose, a sensor is arranged in the spare gas cooler 28, which is omitted from the drawing. In other words, the first stage gas cooler 25 and spare gas cooler 28 may be formed with a symmetrical structure.

As such, by making the first stage gas cooler 25 and the spare gas cooler 28 be symmetrically formed, when clogging occurs in one, it may be switched over to the other, and the gas cooler where clogging occurred may be overhauled. Accordingly, with the evacuation conduit 2 in an operating state, the clogging may be resolved, allowing for the further lengthening of the evacuation conduit 2 life span.

It should be noted that the evacuation elements other than the first stage gas cooler 25, such as the backing pump (mechanical booster pump) 21, the first stage main pump (omitted from the drawing), the second stage main pump (omitted from the drawing), the third stage main pump 24, the fourth stage main pump 26, the second stage gas cooler 27, the fifth stage main pump (omitted from the drawing), and the third stage gas cooler (omitted from the drawing), may also be formed with symmetrical structures.

Various modifications will become possible for those skilled in the art after receiving the teachings of the present disclosure without departing from the scope thereof. Accordingly, the present invention naturally includes various embodiments not specifically mentioned herein. Therefore, the technical scope of the present invention may be limited only by the scope of the patent claims deemed reasonable from the above description.

What is claimed is

1. A vacuum pumping system comprising:
an evacuation conduit, having a sequence of monitoring zones serially assigned in an exhaust direction;
sensors respectively provided to the monitoring zones and independently detecting the conditions of the monitoring zones;
heaters respectively provided to the monitoring zones and being paired with the sensors; and
a control unit receiving data signals from the sensors, comparing the data signals with a threshold value, and when the data signals from a specific sensor exceed the threshold value, selectively supplying heating power to a heater of the monitoring zone where the specific sensor is provided.

2. The vacuum pumping system of claim 1, wherein the evacuation conduit comprising a plurality of evacuation elements in line.

3. The vacuum pumping system of claim 1, wherein one of the sensors includes a vibration gauge.

4. The vacuum pumping system of claim 1, wherein one of the sensors includes a temperature gauge.

5. A vacuum pumping system, being connected such that a group of evacuation elements regulate a fixed evacuation direction, comprising:
a specific evacuation element included among the group of the evacuation elements;
a first valve connected to a suction side piping of the specific evacuation element;
a branching vacuum piping, having an exhaust side piping connected to the first valve;
a second valve connected to other exhaust side piping of the branching vacuum piping;
a bypass piping having a suction side piping connected to the second valve;
other evacuation elements connecting one of the suction side piping to an exhaust side piping of the specific evacuation element, and the other suction side piping to an exhaust side piping of the bypass piping;
sensors connected to at least one of the suction side piping of the specific evacuation element, the exhaust side piping of the specific evacuation element, and a main body of the specific evacuation element; and
a control unit receiving data signals from the sensors, comparing the data signals with a threshold value, and when the data signals exceed the threshold value, respectively supplying signals for closing the first valve and opening the second valve to the first and second valves.

6. The vacuum pumping system of claim 5, wherein one of the sensors includes a vibration gauge.

7. The vacuum pumping system of claim 5, wherein one of the sensors includes a temperature gauge.

8. The vacuum pumping system of claim 5, further comprising a spare evacuation element in-between the second valve and the bypass piping, and comprising a third and fourth valve respectively connected to exhaust piping of the bypass piping and the specific evacuation element.

9. The vacuum pumping system of claim 8, wherein one of the sensors includes a vibration gauge.

10. The vacuum pumping system of claim 8, wherein one of the sensors includes a temperature gauge.

11. A method for monitoring an evacuation conduit comprising:
evacuating a reactive gas and a reaction by-product of the reactive gas by the evacuation conduit having a plurality of monitoring zones serially arranged in an evacuation direction;
independently detecting respective conditions of the monitoring zones by sensors provided respectively to the monitoring zones;
receiving respective data signals from the sensors;
comparing the data signals with a threshold value; and selectively supplying heating power to only a heater of the monitoring zone where the specified sensor is arranged, when the data signals from a specific sensor exceeds the threshold value.

12. The method of claim 11, wherein one of the respective conditions is a vibration.

13. The method of claim 11, wherein one of the respective conditions is a temperature.

14. A method for monitoring an evacuation conduit comprising:
evacuating a reactive gas and a reaction by-product of the reactive gas, by the evacuation conduit, including a first valve connected to a suction side piping of a specific evacuation element, a branching vacuum piping having an exhaust side piping connected to the first valve, a second valve connected to other exhaust side piping of the branching vacuum piping, a bypass piping having a suction side piping connected to the second valve;
detecting a condition of the specific evacuation element by sensors connected to at least one of the suction side piping of the specific evacuation element, the exhaust side piping of the specific evacuation element, and the main body of the specific evacuation element; and
receiving data signals from the sensors, comparing the data signals with a threshold value, and when the data signals from a specific sensor exceeds the threshold value, supplying respectively signals for closing the first valve and opening the second valve to the first and second valves.

15. The method of claim 14, wherein one of the respective conditions is a vibration.

16. The method of claim 14, wherein one of the respective conditions is a temperature.

17. The method of claim 14, further comprising a spare evacuation element in-between the second valve and the bypass piping, and a third and fourth valve, which are respectively connected to exhaust piping of the bypass piping and the specific evacuation element.

18. The method of claim 17, wherein one of the respective conditions is a vibration.

19. The method of claim 17, wherein one of the respective conditions is a temperature.
